(19) United States
(12) Patent Application Publication
(10) Pub. No.: US 2020/0020770 A1
(43) Pub. Date: Jan. 16, 2020

(54) COMPOSITE SPACERS FOR TAILORING THE SHAPE OF THE SOURCE AND DRAIN REGIONS OF A FIELD-EFFECT TRANSISTOR

(71) Applicant: GLOBALFOUNDRIES Inc., Grand Cayman (KY)

(72) Inventors: Yi Qi, Niskayuna, NY (US); Hsien-Ching Lo, Clifton Park, NY (US); Xusheng Wu, Ballston Lake, NY (US); Hui Zang, Guilderland, NY (US); Zhenyu Hu, Clifton Park, NY (US); George R. Mulfinger, Gansevoort, NY (US)

(21) Appl. No.: 16/033,812

(22) Filed: Jul. 12, 2018

(51) Int. Cl. H01L 29/08; H01L 29/66; H01L 21/8234

(52) U.S. Cl. CPC H01L 29/0847; H01L 29/66575; H01L 21/823468; H01L 29/66553

(57) ABSTRACT

Structures for field-effect transistors and methods for forming field-effect transistors. A sidewall spacer is arranged adjacent to a sidewall of a gate structure. The sidewall spacer includes a first section and a second section arranged over the first section. The first section of the sidewall spacer is composed of a first dielectric material, and the second section of the sidewall spacer is composed of a second dielectric material different from the first dielectric material. A source/drain region includes a first section arranged adjacent to the first section of the sidewall spacer and a second section arranged adjacent to the second section of the sidewall spacer. The second section of the source/drain region is spaced by a gap from the second section of the sidewall spacer.

### BACKGROUND

The present invention relates to semiconductor device fabrication and integrated circuits and, more specifically, to structures for field-effect transistors and methods for forming field-effect transistors.

Devices fabricated using silicon-on-insulator (SOI) technologies may exhibit certain performance improvements in comparison with comparable devices built directly in a bulk silicon substrate. Generally, an SOI wafer includes a thin device layer of semiconductor material, a substrate, and a buried oxide (BOX) layer physically separating and electrically isolating the device layer from the substrate.

Device structures for a field-effect transistor generally include a source, a drain, and a gate electrode configured to switch carrier flow in a channel region arranged between the source and drain. The channel region of a planar field-effect transistor is located in the device layer of the SOI wafer. When a control voltage exceeding a designated threshold voltage is applied to the gate electrode, carrier flow occurs in the channel region to produce a device output current.

The sidewalls of the gate electrode are clad by sidewall spacers composed of a single dielectric material. The source and drain may include semiconductor material that is epitaxially grown in the space between the sidewall spacers on adjacent gate electrodes. The shape of the epitaxial semiconductor material, as well as the shape uniformity of the epitaxial semiconductor material across the wafer, may be difficult to control by merely attempting to exercise control over the growth conditions.

Improved structures for field-effect transistors and methods for forming field-effect transistors are needed.

### SUMMARY

In an embodiment of the invention, a structure includes a sidewall spacer arranged adjacent to a sidewall of a gate structure. The sidewall spacer includes a first section and a second section that is arranged over the first section. The first section of the sidewall spacer is composed of a first dielectric material, and the second section of the sidewall spacer is composed of a second dielectric material different from the first dielectric material. The structure further includes a source/drain region with a first section arranged adjacent to the first section of the sidewall spacer and a second section arranged adjacent to the second section of the sidewall spacer. The second section of the source/drain region is spaced by a gap from the second section of the sidewall spacer.

In an embodiment of the invention, a method includes forming a gate structure, forming a first section of a sidewall spacer adjacent to a sidewall of the gate structure, and forming a second section of the sidewall spacer adjacent to the sidewall of the gate structure and over the first section. During a first portion of an epitaxial growth process, a first section of a source/drain region is epitaxially grown that is arranged adjacent to the first section of the sidewall spacer. During a second portion of the epitaxial growth process, a second section of the source/drain region is epitaxially grown that is arranged adjacent to the second section of the sidewall spacer and spaced by a gap from the second section of the sidewall spacer. The first section of the sidewall spacer is composed of a first dielectric material, and the second section of the sidewall spacer is composed of a second dielectric material different from the first dielectric material.

### BRIEF DESCRIPTION OF THE DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention.

FIGS. 1-6 are cross-sectional views of a structure at successive stages of a processing method in accordance with embodiments of the invention.

### DETAILED DESCRIPTION

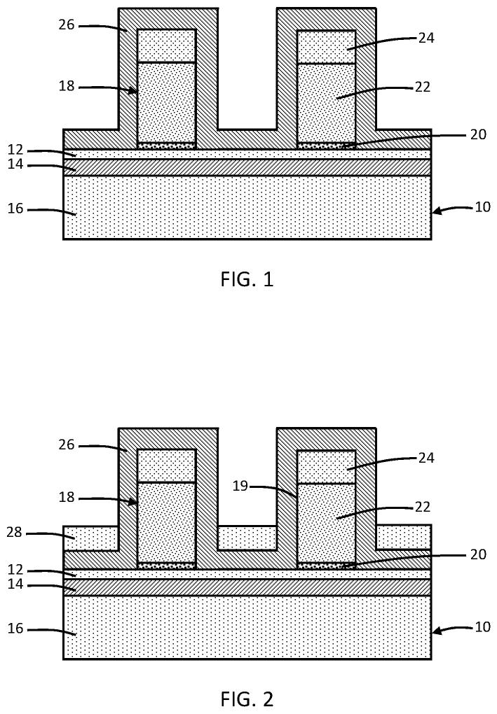

With reference to FIG. 1 and in accordance with an embodiment of the invention, a semiconductor wafer 10 may be a semiconductor-on-insulator (SOI) wafer that includes a device layer 12, a buried oxide (BOX) layer 14, and a substrate 16. The device layer 12 is separated from the substrate 16 by the intervening BOX layer 14 and may be considerably thinner than the substrate 16. The device layer 12 is arranged over the BOX layer 14 and is electrically insulated from the substrate 16 by the BOX layer 14. The BOX layer 14 may be composed of an electrical insulator, such as silicon dioxide (e.g., SiO₂). The device layer 12 and the substrate 16 may be composed of a single-crystal semiconductor material, such as single-crystal silicon (Si). The substrate 16 may be lightly-doped with a p-type dopant from Group V of the Periodic Table (e.g., boron (B) and/or indium (In)) that provides p-type electrical conductivity.

One or more field-effect transistors may be formed using the semiconductor wafer 10. To that end, gate structures 18 are formed on a top surface of the device layer 12. Each gate structure 18 may include a gate electrode 20 and a gate dielectric 22. The gate electrode 20 may be composed of polycrystalline silicon (polysilicon), one or more metals, or combinations of these materials, deposited by physical vapor deposition (PVD), chemical vapor deposition (CVD), etc. The gate dielectric 22 may be composed of a dielectric or insulating material, such as silicon dioxide (SiO₂), a high-k dielectric material such as hafnium oxide (HfO₂), or layered combinations of these dielectric materials, deposited by chemical vapor deposition (CVD), atomic layer deposition (ALD), etc. The gate structures 18 may be formed by patterning a layer stack of their constituent materials with a lithography and etching process. A gate cap 24 may be arranged over each gate structure 18 and may be constituted by a section of a hardmask used to pattern the gate structures 18.

A dielectric layer 26 is formed over the exterior surfaces of the gate structures 18 and gate caps 24, and also over the exposed areas on the top surface of the device layer 12 between the gate structures 18. The dielectric layer 26 may be conformally deposited with a given thickness. The dielectric layer 26 may be composed of a dielectric material or low-k dielectric material, such as silicon-boron-carbon-nitride (SiBCN), conformally deposited by atomic layer deposition (ALD).

With reference to FIG. 2 in which like reference numerals refer to like features in FIG. 1 and at a subsequent fabrication stage of the processing method, an etch mask 28 is formed over the sections of the dielectric layer 26 arranged over the areas of the surface of the device layer 12 exposed between the gate structures 18. The etch mask 28 has a given thickness, t, that may be produced in incremental sub-thicknesses by a cyclic deposition-and-etch process that only forms the sections of the etch mask 28 at the desired locations between the gate structures 18. In an embodiment, the etch mask 28 is composed of an oxide of silicon (e.g., silicon dioxide (SiO₂)) formed by high-density plasma (HDP) deposition using the cyclic deposition-and-etch process.

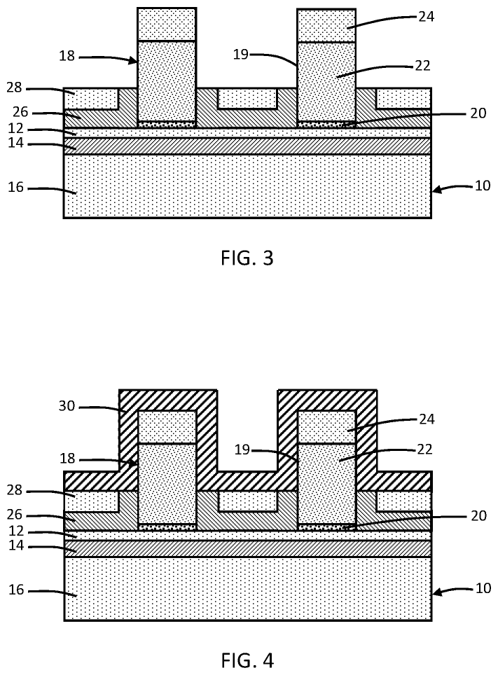

With reference to FIG. 3 in which like reference numerals refer to like features in FIG. 2 and at a subsequent fabrication stage of the processing method, the dielectric layer 26 is etched with a directional etching process, such as reactive ion etching (RIE), with the etch mask 28 present. The masked etching process removes and recesses the conformal dielectric layer 26 such that portions of the sidewalls 19 of each gate structure 18 are exposed. The thickness of the etch mask 28 determines the height of the dielectric layer 26 retained at the sidewalls 19 of each gate structure 18.

With reference to FIG. 4 in which like reference numerals refer to like features in FIG. 3 and at a subsequent fabrication stage of the processing method, a dielectric layer 30 is formed over the exterior surfaces of the gate structures 18 and gate caps 24, and over the etch mask 28 and the underlying sections of dielectric layer 26 between the gate structures 18. The dielectric layer 30 may be conformally deposited with a given thickness. The conformal dielectric layer 30 may be composed of a dielectric material or a low-k dielectric material, such as silicon-oxygen-carbon-nitride (SiOCN), deposited by atomic layer deposition (ALD). In an embodiment, the thickness of the dielectric layer 30 may be equal to the thickness of the dielectric layer 26.

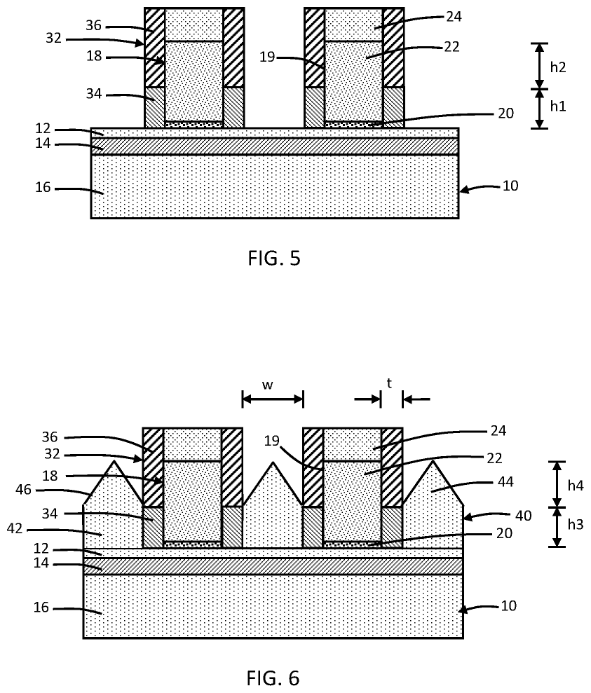

With reference to FIG. 5 in which like reference numerals refer to like features in FIG. 4 and at a subsequent fabrication stage of the processing method, the dielectric layer 26, etch mask 28, and dielectric layer 30 are etched with a directional etching process, such as reactive ion etching (RIE). The etching process removes sections of the conformal dielectric layers 26, 30 and the etch mask 28 between the gate structures 18 such that the corresponding areas on the top surface of the device layer 12 between the gate structures 18 are exposed.

Composite spacers 32 are formed at the sidewalls 19 of the gate structures 18 as a result of the performance of the etching process. In an embodiment, the sidewalls 19 of the gate structures 18 are encircled or surrounded by the composite spacers 32. Each composite spacer 32 includes a lower segment or section 34 resulting from the etching of the conformal dielectric layer 26 and an upper segment or section 36 resulting from the etching of the conformal dielectric layer 30. The sections 34, 36 of each composite spacer 32 are stacked adjacent to the sidewalls 19 of the gate structures 18 with the upper section 36 arranged over the lower section 34, and the lower section 34 arranged in a vertical direction between the device layer 12 and the upper section 36. Each lower section 34 has a height, h1, and each section 36 has a height, h2. The thickness, t, of the etch mask 28 (FIG. 2) determines the relative heights of the sections 34, 36 of the composite spacers 32.

With reference to FIG. 6 in which like reference numerals refer to like features in FIG. 5 and at a subsequent fabrication stage of the processing method, source/drain regions 40 are formed at the sidewalls 19 of the gate structures 18 and adjacent to the composite spacers 32. The source/drain regions 40 may be composed of a semiconductor material that is epitaxially grown from the top surface of the device layer 12. Each of source/drain regions 40, which are raised relative to the top surface of the device layer 12, include a lower section 42 that is arranged adjacent to one of the lower sections 34 of the composite spacers 32, and include an upper section 44 that is arranged adjacent to one of the upper sections 36 of the composite spacers 32. In an embodiment, the transition between the lower section 42 and upper section 44 of each source/drain region 40 occurs proximate to the interface between the sections 34, 36 of the composite spacers 32. As used herein, the term “source/drain region” means a doped region of semiconductor material that can function as either a source or a drain of a field-effect transistor.

The lower section 42 of each source/drain region 40 may extend in a lateral direction from the lower section 34 of the composite spacer 32 at the sidewall of one of the gate structures 18 to the lower section 34 of the composite spacer 32 at the sidewall of the adjacent gate structure 18. In an embodiment, the lower section 42 of each source/drain region 40 has a contacting arrangement with the lower section 34 of the adjacent composite spacers 32. The upper section 44 of each source/drain region 40 is spaced by a gap in a lateral direction from the upper section 36 of the adjacent composite spacers 32. The width of the gap between the upper section 44 of each source/drain region 40 and the upper section 36 of each adjacent composite spacer 32 may increase with increasing distance from the interface with the underlying lower section 42 of the source/drain regions 40.

An epitaxial growth process may be used to form the sections 42, 44 of a semiconductor material, such as silicon germanium (SiGe) or silicon (Si), that provide the source/drain regions 40. The gate structures 18 and composite spacers 32 function to self-align the semiconductor material of the source/drain regions 40 during epitaxial growth. In an embodiment, the source/drain regions 40 are formed by a selective epitaxial growth process in which semiconductor material nucleates for epitaxial growth on semiconductor surfaces, but does not nucleate for epitaxial growth from insulator surfaces (e.g., the gate caps 24 and the composite spacers 32).

The epitaxial growth process may include in situ doping during growth to provide a given electrical conductivity type to the grown semiconductor material. The semiconductor material of the source/drain regions 40 may contain a p-type dopant selected from Group III of the Periodic Table (e.g., boron (B)) that is effective to produce p-type conductivity. Alternatively, the semiconductor material of the source/drain regions 40 may contain an n-type dopant from Group V of the Periodic Table (e.g., phosphorus (P) and/or arsenic (As)) that is effective to produce n-type conductivity.

The composite spacers 32 influence the morphology of the source/drain regions 40 without any modification to the epitaxial growth process forming the source/drain regions 40. In the representative embodiment, the lower sections 42 of the source/drain regions 40 arranged adjacent to the lower sections 34 of the composite spacers 32 have a different morphology than the upper sections 44 of the source/drain regions 40 arranged adjacent to the upper sections 36 of the composite spacers 32. The differing morphologies may result from the growth front for the epitaxial semiconductor material forming the source/drain regions 40 exhibiting a dependence on the different dielectric materials forming the lower section 34 and upper section 36 of each composite spacer 32. The modulation of the growth front may depend on differences in one or more surface properties (e.g., surface energy) of the dielectric material forming the lower section 34 of the composite spacers 32 and the dielectric material forming the upper section 36 of the composite spacers 32.

The lower section 42 of each source/drain region 40 may have a height, h3, and the upper section 44 of each source/drain region 40 may have a height, h4, that can be tailored through the selection of the heights of the sections 34, 36 of the composite spacer 32. In an embodiment, the height, h3, of the lower section 42 of each source/drain region 40 is equal or substantially equal to the height, h1, of the adjacent lower section 34 of the composite spacer 32, and the height, h4, of the upper section 44 of each source/drain region 40 may equal or substantially equal to the height, h2, of the adjacent upper section 36 of the composite spacer 32. The width, w, of the lower section 42 of each source/drain region 40 may be constant or substantially constant over its height, h3. The upper section 44 of each source/drain region 40 may have a width that varies over its height, h4, and that is less than or equal to the width, w, of the underlying lower section 42 over its entire height, h4. Due at least in part to the width variation, the upper section 44 of each source/drain region 40 has a top surface 46 that is non-planar. Each top surface 46 may include inclined sections extending from the lower section 34 to define, for example, a facet or a trapezoidal shape.

Standard silicidation, middle-of-line (MOL) processing, and back-end-of-line (BEOL) processing follow, which includes formation of dielectric layers, contacts, vias, and wiring forming an interconnect structure coupled with the one or more field-effect transistors. For example, contacts may extend vertically through an interlayer dielectric layer to contact the top surface 46 of each source/drain region 40.

The gap between the upper sections 44 and the gate electrodes 20 may operate to lower the fringe capacitance of the field-effect transistor. The wider lower sections 42 of the source/drain regions 40, which have a controllable height through the selection of the height of the lower sections 34 of the composite spacers 32, promote the formation of silicide in connection with silicidation. The identical or substantially identical thicknesses of the stacked lower sections 34 and upper sections 36 of the composite spacers 32 ensure that a minimum spacer thickness is maintained in order to avoid pulldown and loss and to avoid shorting between the gate electrodes 20 and source/drain contacts.

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. In the latter case, the chip is mounted in a single chip package (e.g., a plastic carrier, with leads that are affixed to a motherboard or other higher level carrier) or in a multichip package (e.g., a ceramic carrier that has either or both surface interconnections or buried interconnections). In any case, the chip may be integrated with other chips, discrete circuit elements, and/or other signal processing devices as part of either an intermediate product or an end product.

References herein to terms such as “vertical”, “horizontal”, etc. are made by way of example, and not by way of limitation, to establish a frame of reference. The term “horizontal” as used herein is defined as a plane parallel to a conventional plane of a semiconductor substrate, regardless of its actual three-dimensional spatial orientation. The terms “vertical” and “normal” refer to a direction perpendicular to the horizontal, as just defined. The term “lateral” refers to a direction within the horizontal plane. Terms such as “above” and “below” are used to indicate positioning of elements or structures relative to each other as opposed to relative elevation.

A feature “connected” or “coupled” to or with another element may be directly connected or coupled to the other element or, instead, one or more intervening elements may be present. A feature may be “directly connected” or “directly coupled” to another element if intervening elements are absent. A feature may be “indirectly connected” or “indirectly coupled” to another element if at least one intervening element is present.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A structure comprising:
a gate structure having a sidewall;
a sidewall spacer arranged adjacent to the sidewall of the gate structure, the sidewall spacer including a first section and a second section arranged over the first section, the first section of the sidewall spacer comprised of a first dielectric material, and the second section of the sidewall spacer comprised of a second dielectric material different from the first dielectric material; and
a source/drain region including a first section arranged adjacent to the first section of the sidewall spacer and a second section arranged adjacent to the second section of the sidewall spacer, the second section of the source/drain region spaced by a gap from the second section of the sidewall spacer.

2. The structure of claim 1 wherein the first section of the sidewall spacer has a first thickness, and the second section of the sidewall spacer has a second thickness that is substantially equal to the first thickness.

3. The structure of claim 2 wherein the first section of the sidewall spacer has a first height and the first thickness is substantially constant over the first height, and the second section of the sidewall spacer has a second height and the second thickness over the second height is substantially constant.

4. The structure of claim 1 wherein the first section of the source/drain region has a first height and a first width, and the second section of the source/drain region has a second height and a second width varies over the second height.

5. The structure of claim 4 wherein the second width of the second section of the source/drain region over an entirety of the second height of the second section of the source/drain region is less than or equal to the first width of the first section of the source/drain region.

6. The structure of claim 4 wherein the first width of the first section of the source/drain region is substantially constant over the first height of the first section of the source/drain region.

7. The structure of claim 4 wherein the first section of the sidewall spacer has a first height, the second section of the sidewall spacer has a second height, the first height of the first section of the source/drain region is substantially equal to the first height of the first section of the sidewall spacer, and the second height of the second section of the source/drain region is substantially equal to the second height of the second section of the sidewall spacer.

8. The structure of claim 4 wherein the second section of the source/drain region has a top surface that is faceted.

9. The structure of claim 4 wherein the second section of the source/drain region has a top surface that is non-planar.

10. The structure of claim 1 wherein the first dielectric material is SiBCN, and the second dielectric material is SiOCN.

11. A method comprising:
forming a gate structure;
forming a first section of a sidewall spacer adjacent to a sidewall of the gate structure;
forming a second section of the sidewall spacer adjacent to the sidewall of the gate structure and over the first section; and
epitaxially growing, during a first portion of an epitaxial growth process, a first section of a source/drain region that is arranged adjacent to the first section of the sidewall spacer; and
epitaxially growing, during a second portion of the epitaxial growth process, a second section of the source/drain region that is arranged adjacent to the second section of the sidewall spacer and spaced by a gap from the second section of the sidewall spacer,
wherein the first section of the sidewall spacer is comprised of a first dielectric material, and the second section of the sidewall spacer is comprised of a second dielectric material different from the first dielectric material.

12. The method of claim 11 wherein the first section of the sidewall spacer and the second section of the sidewall spacer are concurrently formed using a directional etching process.

13. The method of claim 11 wherein forming the first section of the sidewall spacer adjacent to the sidewall of the gate structure comprises:
depositing a first conformal layer arranged in part at the sidewall of the gate structure and arranged in part on a semiconductor layer adjacent to the sidewall of the gate structure;
forming an etch mask covering a first portion of the first conformal layer at the sidewall of the gate structure; and
removing a second portion of the first conformal layer at the sidewall of the gate structure that is arranged above the first portion of the first conformal layer with a first etching process,
wherein the first conformal layer is comprised of the first dielectric material.

14. The method of claim 13 wherein forming the second section of the sidewall spacer adjacent to the sidewall of the gate structure comprises:
depositing a second conformal layer arranged in part at the second portion of the sidewall of the gate structure and in part over the etch mask,
wherein the second conformal layer is comprised of the second dielectric material.

15. The method of claim 14 wherein the first section of the sidewall spacer and the second section of the sidewall spacer are respectively formed from the first conformal layer and the second conformal layer by a second etching process.

16. The method of claim 11 wherein the first section of the sidewall spacer has a first thickness, and the second section of the sidewall spacer has a second thickness that is substantially equal to the first thickness.

17. The method of claim 11 wherein the first section of the source/drain region has a first height and a first width, the second section of the source/drain region has a second height and a second width varies over the second height.

18. The method of claim 17 wherein the second section of the source/drain region has a top surface that is faceted.

19. The method of claim 17 wherein the second section of the source/drain region has a top surface that is non-planar.

20. The method of claim 11 wherein the first dielectric material is SiBCN, and the second dielectric material is SiOCN.
